(19) United States
(12) Patent Application Publication
(10) Pub. No.: US 2017/0138103 A1
(43) Pub. Date: May 18, 2017

(54) PIVOTING MECHANISM

(71) Applicant: Acer Incorporated, New Taipei City (TW)

(72) Inventors: Syuan-Hui Hong, New Taipei City (TW); Shun-Bin Chen, New Taipei City (TW); Ming-Yen Wu, New Taipei City (TW)

(73) Assignee: Acer Incorporated, New Taipei City (TW)

(21) Appl. No.: 15/273,504

(22) Filed: Sep. 22, 2016

(30) Foreign Application Priority Data
Nov. 17, 2015 (TW) 104137828

(51) Int. Cl. E05D 3/18; H05K 5/02; E05D 5/06

(52) U.S. Cl. CPC E05D 3/18; E05D 5/06; H05K 5/0226; E05Y 2900/606; G06F 1/1681

(57) ABSTRACT

A pivoting mechanism, including a first bracket, a second bracket, at least one first crank, and at least one second crank, is provided. The first bracket connecting a first body of an electronic device has a first slot. The second bracket connecting a second body has a second slot. The first crank has a first end slidably and rotatably coupled to the first slot, a second end pivoted to the second bracket, and a first pivoting portion. The second crank has a third end slidably and rotatably coupled to the second slot, a fourth end pivoted to the first bracket, and a second pivoting portion. The first and second pivoting portions are connected to form a rotation center, such that the first and second cranks are rotated about the rotation center and the first and second ends slide in the first and second slots respectively.

### CROSS-REFERENCE TO RELATED APPLICATION

This application claims the priority benefit of Taiwan application serial no. 104137828, filed on Nov. 17, 2015. The entirety of the above-mentioned patent application is hereby incorporated by reference herein and made a part of this specification.

### BACKGROUND OF THE INVENTION

Field of the Invention

The invention relates to a pivoting mechanism.

Description of Related Art

Electronic devices, such as the traditional laptop computers, mobile phones, PDA, digital cameras, and electronic books, that can be folded and unfolded are usually provided with a single rotary shaft between different bodies, such as the main body and the screen, or the body and a support frame. The rotary shaft can be driven to rotate by a force for folding or unfolding the bodies, so as to facilitate use and storage of the electronic devices. However, such electronic devices with one single rotary shaft usually have a small unfolded angle. Even though some may be able to provide a large-angle pivoting function, they may have a noticeable mechanism outside the bodies due to structural interference, which affects the appearance.

Therefore, how to achieve a large-angle pivoting function without sacrificing the appearance (i.e. a hidden mechanism) to improve the convenience of use of the electronic devices is an issue that needs to be addressed.

### SUMMARY OF THE INVENTION

The invention provides a pivoting mechanism, which connects two bodies of an electronic device for the two bodies to pivot with respect to each other.

The invention provides a pivoting mechanism, which connects a first body and a second body of an electronic device for the first body and the second body to pivot with respect to each other. The pivoting mechanism includes a first bracket, a second bracket, at least one first crank, and at least one second crank. The first bracket is connected to the first body of the electronic device and has a first slot. The second bracket is connected to the second body of the electronic device and has a second slot. The first crank has a first end, a second end, and a first pivoting portion. The first end is slidably and rotatably coupled to the first slot, and the second end is pivoted to the second bracket. The second crank has a third end, a fourth end, and a second pivoting portion. The third end is slidably and rotatably coupled to the second slot, and the fourth end is pivoted to the first bracket. The second pivoting portion is pivoted to the first pivoting portion to form a rotation center, such that the first crank and the second crank are rotated with respect to each other about the rotation center and the first end and the second end slide in the first slot and the second slot respectively.

Based on the above, the pivoting mechanism is provided with the first bracket, the second bracket, at least one first crank, and at least one second crank, wherein one end of the crank is pivoted to one bracket while another end of the crank is slidably coupled to the other bracket, which allows the another end to move along the slot on the bracket while the paired cranks are pivoted with respect to the brackets, thereby forming a nearly-biaxial pivoting mechanism. Moreover, the sliding further increases the degree of freedom, and thus structural interference is prevented effectively. Accordingly, with the pivoting mechanism disposed and connected between the first body and the second body of the electronic device, the first body and the second body are pivoted with respect to each other more smoothly, and the movement path that may interfere with the pivoting of the bodies is avoided, so as to make the electronic device convenient to operate and improve the appearance.

To make the aforementioned and other features and advantages of the invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic view showing an electronic device according to an embodiment of the invention.

FIG. 2 is a partial schematic view showing a pivoting mechanism according to an embodiment of the invention.

FIG. 3 to FIG. 5 are schematic side views respectively showing the pivoting mechanism of FIG. 2.

FIG. 6 is a schematic view showing a pivoting mechanism according to another embodiment of the invention.

FIG. 7 to FIG. 9 are schematic side views showing the pivoting mechanism of FIG. 6.

### DESCRIPTION OF THE EMBODIMENTS

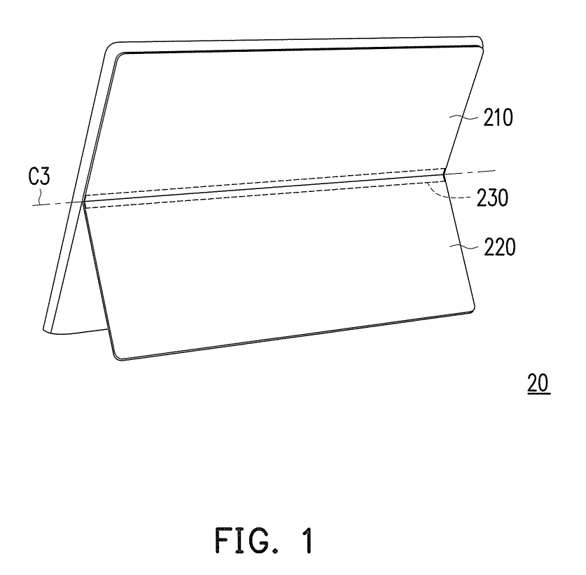

FIG. 1 is a schematic view showing an electronic device according to an embodiment of the invention. With reference to FIG. 1, an electronic device 200 as shown in the figure is a tablet computer, for example, and includes a first body 210 and a second body 220, wherein the second body 220 may be pivoted or rotated with respect to the first body 210 along an axis C3 through pivoting members (not shown here but will be described in detail later) disposed in a pivoting region 230, and when the first body 210 and the second body 220 are unfolded with respect to each other (a state where the second body 220 and the first body 210 are unfolded to be even after the second body 220 is closed and accommodated, as indicated by the one-way arrow in FIG. 1), a gap between the structures (the first body 210 and the second body 220) is minimized.

Nevertheless, the invention is not intended to limit the type of the electronic device 200, and a pivoting mechanism of the invention (will be described later) may be applied to any case that requires two bodies to pivot with respect to each other.

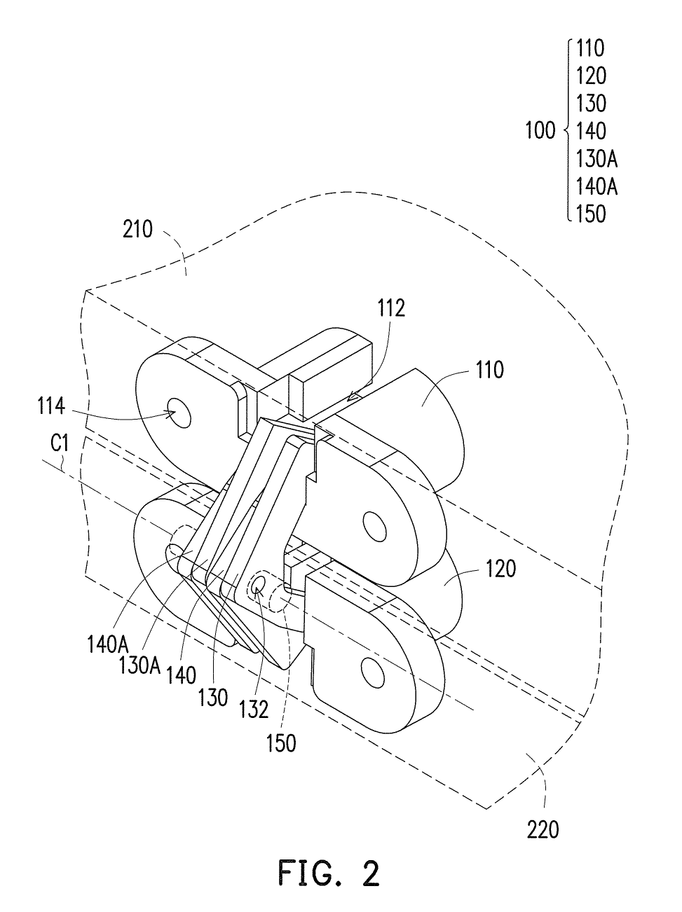

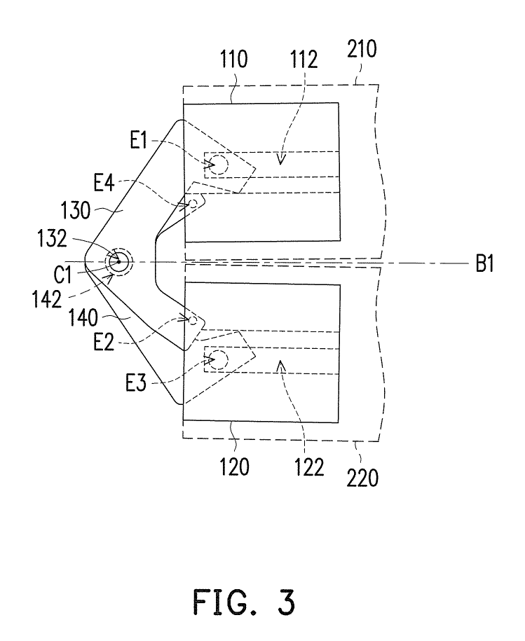

FIG. 2 is a partial schematic view showing the pivoting mechanism according to an embodiment of the invention, which is applied to the electronic device 200 of FIG. 1 for the first body 210 and the second body 220 to pivot with respect to each other. FIG. 3 to FIG. 5 are schematic side views respectively showing the pivoting mechanism of FIG. 2, wherein FIG. 2 to FIG. 5 illustrate the first body 210 and the second body 220 in a perspective manner (with dotted contour lines), so as to clearly show members of the pivoting mechanism 100.

With reference to FIG. 2 to FIG. 5, in this embodiment, the pivoting mechanism 100 is disposed in the pivoting region 230 in the bodies as shown in FIG. 1. The pivoting mechanism 100 includes a first bracket 110, a second bracket 120, first cranks 130 and 130A, and second cranks 140 and 140A, wherein the first cranks 130 and 130A and the second cranks 140 and 140A respectively connect between the first bracket 110 and the second bracket 120, and the cranks are pivoted to each other. It should be noted that, although four crank members are illustrated in this embodiment, the cranks 130 and 130A have the same motion and function while the cranks 140 and 140A have the same motion and function, and therefore, in FIG. 3 to FIG. 5, only the first crank 130 and the second crank 140 are shown as an example.

Specifically, the first bracket 110 and the second bracket 120 are respectively connected to the first body 210 and the second body 220, as shown in FIG. 3. The first bracket 110 has a convex profile, and a locking member (e.g. a screw, not shown here) passes through two lock holes 114 (only one is shown here) on a wing portion of the first bracket 110 to be locked and fixed to the first body 210. The second bracket 120 is fixed to the second body 220 in the same manner and thus details thereof are omitted.

Moreover, the first bracket 110 has a first slot 112 and the second bracket 120 has a second slot 122. The first crank 130 has a first end E1, a second end E2, and a first pivoting portion 132 while the second crank 140 has a third end E3, a fourth end E4, and a second pivoting portion 142. In this embodiment, the first end E1 is slidably and rotatably coupled to the first slot 112, and the second end E2 is pivoted to the second bracket 120. The third end E3 is slidably and rotatably coupled to the second slot 122, and the fourth end E4 is pivoted to the first bracket 110. The first pivoting portion 132 is located at a bent portion of the first crank 130 and the second pivoting portion 142 is located at a bent portion of the second crank 140. It should be noted that the first pivoting portion 132 and the second pivoting portion 142 are pivoted to each other to form a rotation center C1. In other words, the pivoting portions of the first cranks 130 and 130A and the second cranks 140 and 140A are pivoted together to be pivoted about the rotation center C1.

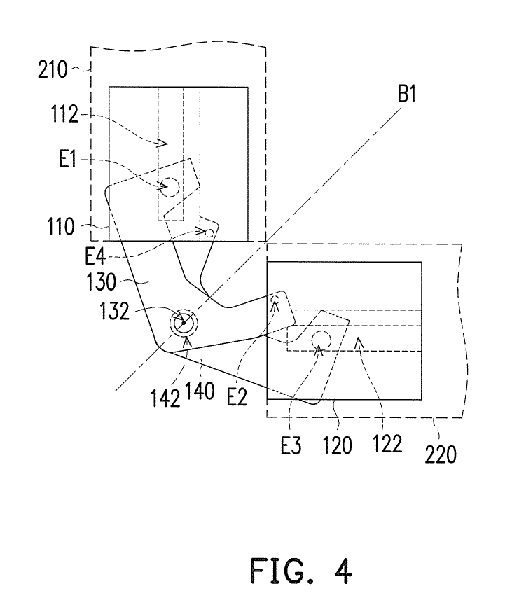

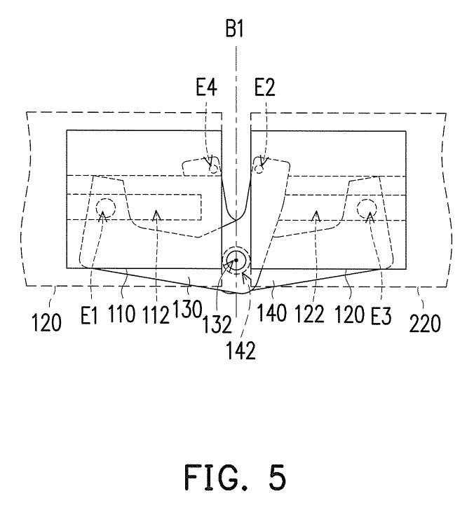

Based on the above, when the user applies a force on the first body 210 or the second body 220 to cause the first body 210 and the second body 220 to pivot with respect to each other, the first crank 130 and the second crank 140 (including the first bracket 110 and the second bracket 120) rotate about the rotation center C1, and at the same time, the first end E1 and the third end E3 respectively slide (and rotate) in the first slot 112 and the second slot 122, and the first crank 130 and the second crank 140 respectively rotate with respect to the first bracket 110 and the second bracket 120 by the second E2 and the fourth end E4, so as to shift the first body 210 and the second body 220 between a first state shown in FIG. 3 and a second state shown in FIG. 5 (FIG. 4 illustrates an intermediate state between the first state and the second state).

Accordingly, with the paired structural configuration of two cranks (the first cranks 130 and 130A and the second cranks 140 and 140A), parts of the cranks are allowed to slide in the slots of the brackets. Therefore, the first bracket 110 and the second bracket 120 is easily shifted between the first state (folded state) and the second state (unfolded state), such that the first bracket 110 and the second bracket 120 do not interfere with each other during the shift. That is, in the second state, the gap between the brackets is reduced due to the aforementioned structural configuration, or even eliminated.

In other words, because the first cranks 130 and 130A and the second cranks 140 and 140A of this embodiment are alternately arranged along the rotation center C1 to be connected in series, and the rotation center C1 is located outside the first bracket 110 and the second bracket 120 (equivalent to being outside the first body 210 and the second body 220), the first body 210 and the second body 220 may pivot around a center outside the members to prevent structural interference.

In the side views (FIG. 3 to FIG. 5), the brackets and cranks of this embodiment are arranged in a symmetrical configuration with respect to a plane B1 in a minor-image manner where the rotation center C1 is located. Because they have the same relative movement stroke, the first body 210 and the second body 220 move symmetrically, which facilitates the pivoting process of the first body 210 and the second body 220.

It should also be noted that the pivoting mechanism 100 further includes a hinge 150 assembled to a pivoting joint of the first pivoting portion 132 and the second pivoting portion 142. That is, the hinge 150 is disposed along the rotation center C1, so as to provide a torsion between the first crank 130 and the second crank 140, such that the first bracket 110 (including the first body 210) and the second bracket 120 (including the second body 220) may be supported by the torsion of the hinge 150 at any unfolded angle.

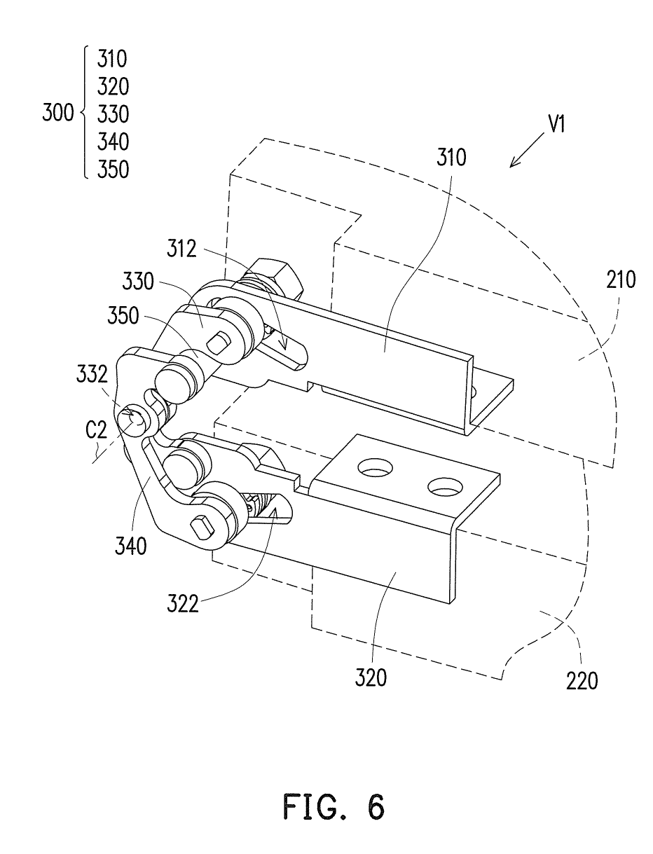

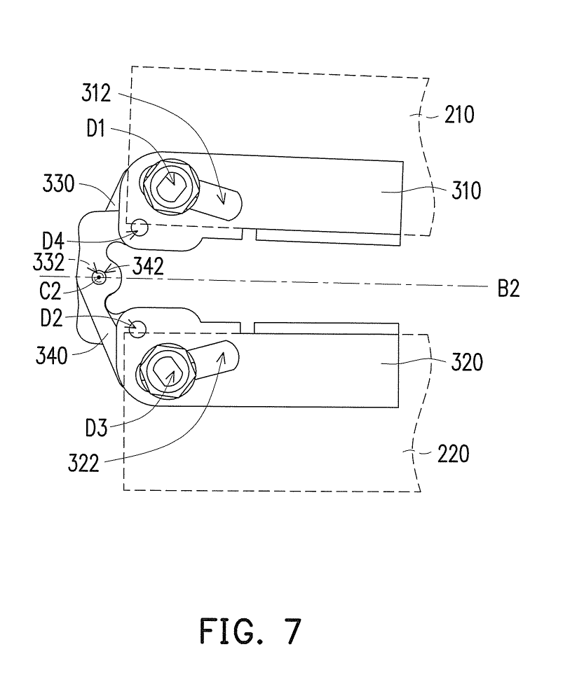

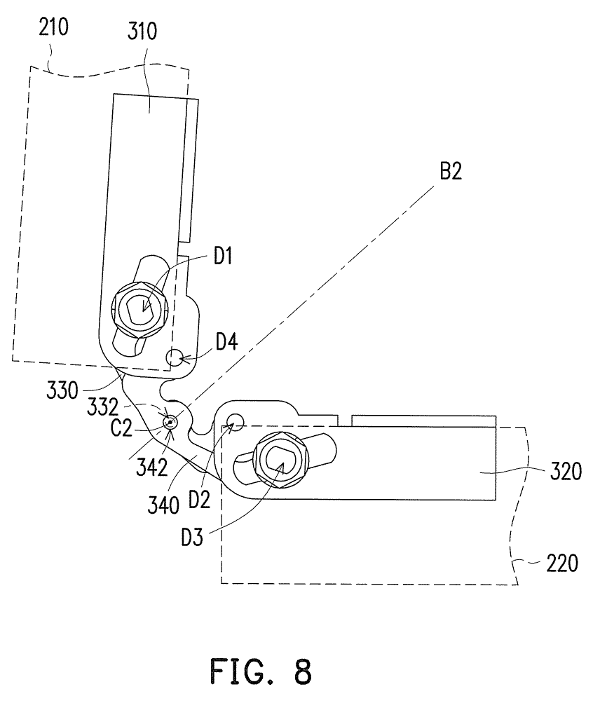

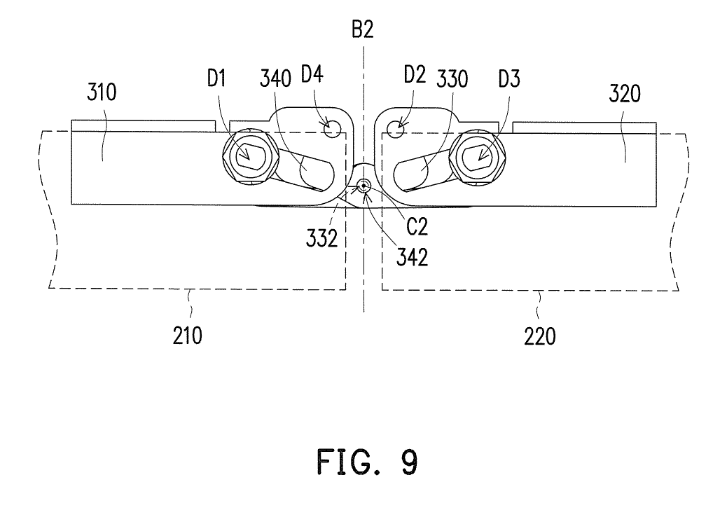

FIG. 6 is a schematic view showing a pivoting mechanism according to another embodiment of the invention, which is also applicable between the first body 210 and the second body 220 of FIG. 1. FIG. 7 to FIG. 9 are schematic side views showing the pivoting mechanism of FIG. 6 and illustrate different pivoting states of the pivoting mechanism from a perspective V1. In this embodiment, a pivoting mechanism 300 includes a first bracket 310, a second bracket 320, a first crank 330, and a second crank 340. Like the previous embodiment, the first bracket 310 is connected to the first body 210 and has a first slot 312, the second bracket 320 is connected to the second body 220 and has a second slot 322, a first end D1 of the first crank 330 is slidably and rotatably coupled to the first slot 312, a second end D2 is pivoted to the second bracket 320, a third end D3 of the second crank 340 is slidably and rotatably coupled to the second slot 322, a fourth end D4 is pivoted to the first bracket 310, and a first pivoting portion 332 of the first crank 330 and a second pivoting portion 342 of the second crank 340 are pivoted to each other to form a rotation center C2 for the foregoing members to pivot with respect to each other around the rotation center C2.

Here, the members are also arranged in a symmetrical configuration of mirror-image with respect to the plane B2 where the rotation center C2 is located, such that the pivoting mechanism 300 of this embodiment achieves the same pivoting effect as the previous embodiment. A difference between this embodiment and the previous embodiment is that, as shown in FIG. 6, the pivoting mechanism 300 of this embodiment further includes a hinge 350 disposed at a pivoting joint of the fourth end D4 of the second crank 340 and the first bracket 310, not at the rotation center C2. In this way, the hinge 350 also provides the pivoting mechanism 300 a torsion to achieve the aforementioned support effect. In other words, in the pivoting mechanism 300 of this embodiment, the hinge 350 may be disposed at the rotation center C2, the pivoting joint of the second end D2 and the second bracket 320, or the pivoting joint of the fourth end D4 and the first bracket 310.

To sum up, in the above embodiments of the invention, the pivoting mechanism is provided with the first bracket, the second bracket, at least one first crank, and at least one second crank, wherein one end of the crank is pivoted to one bracket while another end of the crank is slidably coupled to the other bracket, which allows the another end to move along the slot on the bracket while the paired cranks are pivoted with respect to the brackets, thereby forming a nearly-biaxial pivoting mechanism. Because the rotation center is located outside the brackets, interference between the brackets and the bodies connected thereto during the pivoting process is prevented effectively. Moreover, one end of the crank is still movable in the slot of the bracket. Therefore, in addition to the biaxial pivoting described above, the degree of freedom in movement is increased, so as to facilitate the pivoting process of the brackets (and the bodies). Meanwhile, the relative distance between the bodies is also reduced in the pivoting process, which helps to reduce the gap between the bodies and improve the appearance of the bodies.

Furthermore, the pivoting mechanism is arranged in a symmetrical configuration with respect to the plane where the rotation center is located, and the relative movement between the cranks and the brackets is also symmetrical, which allows the pivoting mechanism to provide a symmetrical movement pattern between the first body and the second body and helps to facilitate the pivoting process of the first body and the second body.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A pivoting mechanism connecting a first body and a second body of an electronic device for the first body and the second body to pivot with respect to each other, the pivoting mechanism comprising:
a first bracket connecting the first body and comprising a first slot;
a second bracket connecting the second body and comprising a second slot;
at least one first crank comprising a first end, a second end, and a first pivoting portion, wherein the first end is slidably and rotatably coupled to the first slot, and the second end is pivoted to the second bracket; and
at least one second crank comprising a third end, a fourth end, and a second pivoting portion, wherein the third end is slidably and rotatably coupled to the second slot, and the fourth end is pivoted to the first bracket, wherein the second pivoting portion is pivoted to the first pivoting portion to form a rotation center, and the first crank and the second crank are rotated with respect to each other about the rotation center, such that the first end and the second end respectively slide in the first slot and the second slot to cause the first body and the second body to pivot with respect to each other.

2. The pivoting mechanism according to claim 1, wherein the first crank and the second crank are arranged in a symmetrical configuration with respect to the rotation center and the first slot and the second slot are arranged symmetrically with respect to the rotation center, and the first end and the second end slide and rotate symmetrically in the first slot and the second slot respectively.

3. The pivoting mechanism according to claim 1, wherein the first bracket and the second bracket are shifted between a first state and a second state, wherein the first bracket and the second bracket are folded on each other in the first state and unfolded to be even in the second state.

4. The pivoting mechanism according to claim 3, wherein the first slot and the second slot are on two different but parallel planes in the first state and are on the same plane in the second state.

5. The pivoting mechanism according to claim 1, further comprising:
a hinge assembled to a pivoting joint of the first pivoting portion and the second pivoting portion.

6. The pivoting mechanism according to claim 1, further comprising:
a hinge assembled to a pivoting joint of the second end and the second bracket, or a pivoting joint of the fourth end and the first bracket.

7. The pivoting mechanism according to claim 1, wherein the first pivoting portion and the second pivoting portion are respectively located at a bent portion of the first crank and a bent portion of the second crank.

8. The pivoting mechanism according to claim 1, comprising a pair of first cranks and a pair of second cranks that are alternately arranged and pivoted together.
